(19) United States
(12) Patent Application Publication
(10) Pub. No.: US 2024/0387562 A1
(43) Pub. Date: Nov. 21, 2024

(54) DISPLAY DEVICE

(71) Applicant: Japan Display Inc., Tokyo (JP)

(72) Inventors: Yoshikatsu IMAZEKI, Tokyo (JP); Yoichi KAMIJO, Tokyo (JP); Koichi MIYASAKA, Tokyo (JP); Shuichi OSAWA, Tokyo (JP); Yoshifumi KAMEI, Tokyo (JP)

(73) Assignee: Japan Display Inc., Tokyo (JP)

(21) Appl. No.: 18/789,950

(22) Filed: Jul. 31, 2024

Related U.S. Application Data
(63) Continuation of application No. PCT/JP2022/046742, filed on Dec. 19, 2022.

(30) Foreign Application Priority Data
Feb. 4, 2022 (JP) 2022-016134

(51) Int. Cl. H01L 27/12; H01L 25/16

(52) U.S. Cl. CPC H01L 27/124; H01L 25/167

(57) ABSTRACT

Each of a first wiring and a second wiring of a display device includes a first metal wiring portion made of a first metal material such as copper or a copper alloy and a second metal wiring portion electrically connected to the first metal wiring portion and made of a second metal material different from the first metal material. In a first region overlapping with a semiconductor layer, the second metal wiring portion is arranged and the first metal wiring portion is not arranged. In a second region which is arranged so as to surround the first region and does not overlap with the semiconductor layer, each of the first metal wiring portion and the second metal wiring portion is arranged. The second metal wiring portion arranged in the first region is covered with an organic insulating film.

### CROSS-REFERENCE TO RELATED APPLICATIONS

The present application is a continuation of International Application No. PCT/JP2022/046742 filed on Dec. 19, 2022 and claims priority to Japanese Patent Application No. 2022-016134 filed on Feb. 4, 2022, the disclosure of each are incorporated herein by reference.

### TECHNICAL FIELD

The present invention relates to a display device.

### BACKGROUND

As a display device, there is an LED (Light Emitting Diode) display device in which light emitting diode elements which are self-luminous elements are arranged in a matrix on a substrate (see, for example, Patent Document 1 (US Patent Application Publication No. 2018/0033853)). Patent Document 1 describes a semiconductor device in which a wiring path connected to an anode and a wiring path connected to a cathode are formed in the same layer and an electrical jumper is mounted at the portion in which these wiring paths intersect.

### SUMMARY

An LED display device includes a plurality of LED elements mounted on an array substrate and a plurality of wirings for supplying power to each of the plurality of LED elements. Also, the LED display device includes a transistor having a semiconductor layer as a switching element for controlling the lighting on and off of the plurality of LEDs. The inventors of this application have studied a display device using the wiring made of copper (Cu) in order to reduce the resistance of the plurality of wirings. When copper is used as the wiring material, a technique for suppressing the diffusion of copper into an inorganic insulating layer and a semiconductor layer provided in the switching element is necessary.

An object of the present invention is to provide a technique for improving the performance of the LED display device.

A display device according to an embodiment includes: a plurality of pixels including a first pixel and arranged in a matrix; a first switching element formed in the first pixel; a first light emitting element mounted in the first pixel; a first wiring electrically connected to each of a drain electrode of the first switching element and an anode electrode of the first light emitting element; and a second wiring connected to a source electrode of the first switching element. The first switching element includes: a first inorganic insulating layer formed on a first substrate; a semiconductor layer formed on the first inorganic insulating layer; the drain electrode connected to a drain region of the semiconductor layer; the source electrode connected to a source region of the semiconductor layer; and a second inorganic insulating layer configured to cover the semiconductor layer. Each of the first wiring and the second wiring includes: a first metal wiring portion made of a first metal material such as copper or a copper alloy; and a second metal wiring portion electrically connected to the first metal wiring portion and made of a second metal material different from the first metal material. The second metal wiring portion is arranged and the first metal wiring portion is not arranged in a first region which overlaps with the semiconductor layer. Each of the first metal wiring portion and the second metal wiring portion extending while overlapping with the first metal wiring portion is arranged in a second region which is arranged so as to surround the first region and does not overlap with the semiconductor layer. The second metal wiring portion arranged in the first region is covered with an organic insulating film.

### BRIEF DESCRIPTION OF DRAWINGS

FIG. 1 is a plan view showing a configuration example of a display device according to an embodiment.

FIG. 2 is a circuit diagram showing a configuration example of a circuit around a pixel shown in FIG. 1.

FIG. 3 is an enlarged transparent plan view showing an example of a peripheral structure of an LED element arranged in each of a plurality of pixels of the display device shown in FIG. 1.

FIG. 4 is an enlarged cross-sectional view taken along the line A-A in FIG. 3.

FIG. 5 is an enlarged cross-sectional view showing a modification related to FIG. 4.

FIG. 6 is an enlarged cross-sectional view showing a configuration example of a metal wiring portion shown in FIG. 4 and FIG. 5.

FIG. 7 is an enlarged cross-sectional view showing a modification related to FIG. 6.

FIG. 8 is an enlarged cross-sectional view showing another modification related to FIG. 6.

FIG. 9 is an enlarged cross-sectional view taken along the line B-B in FIG. 3.

FIG. 10 is an enlarged cross-sectional view showing a modification related to FIG. 9.

FIG. 11 is a transparent plan view showing a modification related to FIG. 3.

FIG. 12 is an enlarged cross-sectional view taken along the line C-C in FIG. 11.

FIG. 13 is an enlarged cross-sectional view taken along the line D-D in FIG. 11.

FIG. 14 is an enlarged cross-sectional view showing a modification related to FIG. 13.

FIG. 15 is an enlarged cross-sectional view showing another modification related to FIG. 4.

FIG. 16 is an enlarged cross-sectional view showing another modification related to FIG. 4.

### DETAILED DESCRIPTION OF THE INVENTION

Hereinafter, each embodiment of the present invention will be described with reference to drawings. Note that the disclosure is merely an example, and it is a matter of course that any alteration that a person skilled in the art easily conceives of while keeping a gist of the present invention is included in the range of the present invention. In addition, the drawings schematically illustrate a width, a thickness, a shape, and the like of each portion as compared with actual aspects in order to make the description clearer, but the drawings are merely examples and do not limit the interpretation of the present invention. Further, the same elements as those described in relation to the foregoing drawings are denoted by the same or related reference characters in this specification and the respective drawings, and detailed descriptions thereof will be omitted as appropriate.

In the following embodiment, a micro LED display device provided with a plurality of micro LED elements will be described as an example of a display device using a plurality of light emitting elements (specifically, inorganic light emitting elements). The micro LED element has a smaller element size (outer diameter dimension) than general LED elements, and thus has the advantage of being able to display high-definition images.

Note that there is an organic light emitting diode (OLED) element as an example of a light emitting diode element which is a self-luminous element. The light emitting diode element (micro LED element) described in the following embodiment is an inorganic light emitting diode element and is distinguished from the organic light emitting diode element.

### Display Device

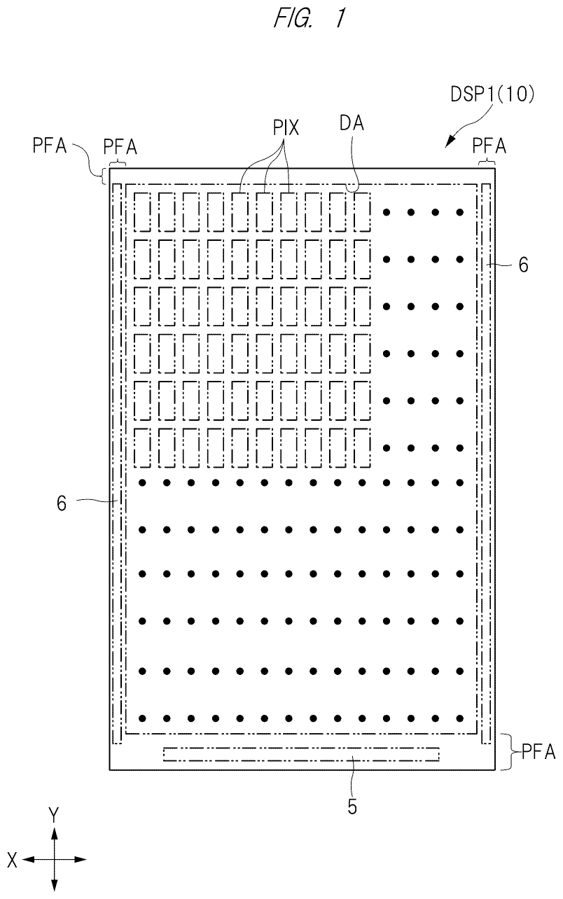

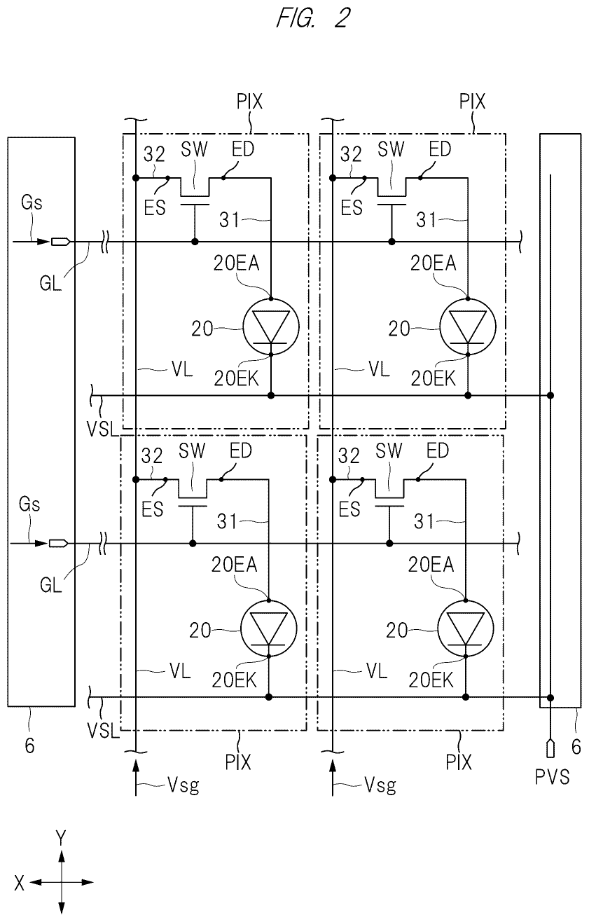

First, a configuration example of a micro LED display device which is a display device according to the present embodiment will be described. FIG. 1 is a plan view showing a configuration example of a display device according to an embodiment. In FIG. 1, each of a boundary between a display region DA and a peripheral region PFA, a control circuit 5, a drive circuit 6, and a plurality of pixels PIX is indicated by two-dot dash lines. FIG. 2 is a circuit diagram showing a configuration example of a circuit around the pixel shown in FIG. 1.

As shown in FIG. 1, a display device DSP1 according to the present embodiment includes the display region DA, the peripheral region PFA having a frame shape and surrounding the display region DA, and the plurality of pixels PIX arranged in a matrix in the display region DA. The display device DSP1 further includes a substrate 10, the control circuit 5 formed on the substrate 10, and the drive circuit 6 formed on the substrate 10.

The control circuit 5 is a control circuit which controls the driving of the display function of the display device DSP1. For example, the control circuit 5 is a driver IC (Integrated Circuit) mounted on the substrate 10. In the example shown in FIG. 1, the control circuit 5 is arranged along one short side of the four sides of the substrate 10. Further, in the present embodiment, the control circuit 5 includes a signal line drive circuit which drives video signal wirings VL (see FIG. 2) connected to the plurality of pixels PIX. However, the position and configuration of the control circuit 5 are not limited to the example shown in FIG. 1, and there are various modifications. For example, there is a case in which a circuit board such as a flexible board is connected to the position shown as the control circuit 5 in FIG. 1 and the driver IC described above is mounted on the circuit board. Furthermore, for example, there is a case in which the signal line drive circuit which drives the video signal wirings VL is formed separately from the control circuit 5.

The drive circuit 6 includes a circuit for driving scanning signal lines GL (see FIG. 2 described later) of the plurality of pixels PIX. The drive circuit 6 further includes a circuit which supplies a reference potential to the LED element mounted in each of the plurality of pixels PIX. The drive circuit 6 drives the plurality of scanning signal lines GL based on a control signal from the control circuit 5. In the example shown in FIG. 1, the drive circuits 6 are arranged along each of two long sides of the four sides of the substrate 10. However, the position and configuration of the drive circuit 6 are not limited to the example shown in FIG. 1, and there are various modifications. For example, there is a case in which a circuit board such as a flexible board is connected to the position shown as the control circuit 5 in FIG. 1 and the drive circuit 6 described above is mounted on the circuit board.

Next, an example of the circuit configuration of the pixel PIX will be described with reference to FIG. 2. Note that four pixels PIX are representatively illustrated in FIG. 2, but each of the plurality of pixels PIX shown in FIG. 1 includes the circuit similar to that of the pixel PIX shown in FIG. 2. Hereinafter, the circuit including a switch and an LED element 20 provided in the pixel PIX is referred to as a pixel circuit in some cases. The pixel circuit is a voltage signal circuit which controls the light emission state of the LED element 20 in accordance with a video signal Vsg supplied from the control circuit 5 (see FIG. 1).

As shown in FIG. 2, the pixel PIX includes the LED element 20. The LED element 20 is the micro light emitting diode described above. The LED element 20 has an anode electrode 20EA and a cathode electrode 20EK. The cathode electrode 20EK of the LED element 20 is connected to a wiring VSL to which a reference potential (fixed potential) PVS is supplied. The anode electrode 20EA of the LED element 20 is electrically connected to a drain electrode ED of a switching element SW via a wiring 31.

The pixel PIX includes the switching element SW. The switching element SW is a transistor which controls the connection state (on or off state) between the pixel circuit and the video signal wiring VL in response to a control signal Gs. The switching element SW is, for example, a thin film transistor. When the switching element SW is in an on state, the video signal Vsg is input to the pixel circuit from the video signal wiring VL.

The drive circuit 6 includes a shift register circuit, an output buffer circuit, and the like (not shown). The drive circuit 6 outputs a pulse based on a horizontal scanning start pulse transmitted from the control circuit 5 (see FIG. 1), and thus outputs the control signal Gs.

Each of the plurality of scanning signal lines GL extends in an X direction. The scanning signal line GL is connected to a gate electrode of the switching element SW. When the control signal Gs is supplied to the scanning signal line GL, the switching element SW is turned on, and the video signal Vsg is supplied to the LED element 20.

### Peripheral Structure of LED Element

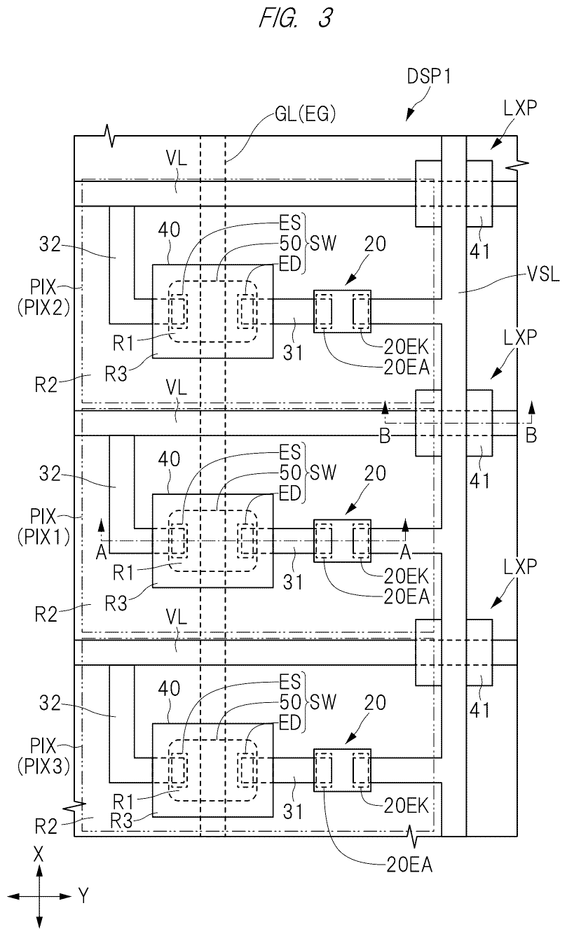

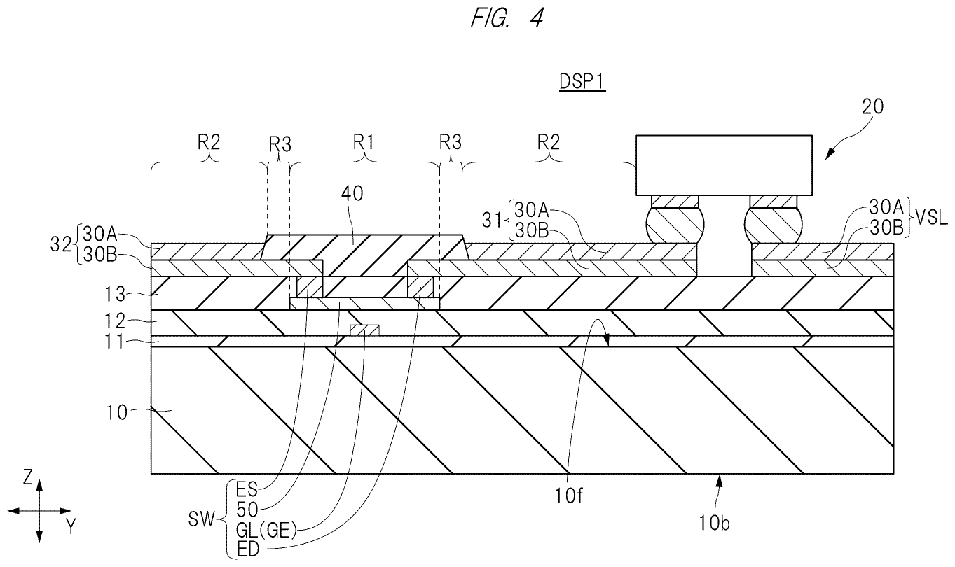

Next, the peripheral structure of the LED element arranged in each of the plurality of pixels PIX shown in FIG. 1 will be described. FIG. 3 is an enlarged transparent plan view showing an example of a peripheral structure of the LED element arranged in each of the plurality of pixels of the display device shown in FIG. 1. FIG. 4 is an enlarged cross-sectional view taken along the line A-A in FIG. 3. In FIG. 3, the outlines of the semiconductor layers, electrodes, and scanning signal lines are indicated by dotted lines.

As shown in FIG. 3, the display device DSP1 is provided with the plurality of pixels PIX including a pixel PIX1 (pixels PIX1, PIX2, and PIX3 in the example shown in FIG. 3). Each of the plurality of pixels PIX has the switching element SW, the LED element (light emitting element) 20, the wiring 31, and a wiring 32. In each of the pixels PIX1, PIX2, and PIX3, the LED element 20 which emits visible light of one color, for example, red, green, or blue is mounted, and the switching element SW which drives the LED element 20 is formed. Color display is possible by controlling the output and timing of visible light emitted from the LED elements of the pixels PIX1, PIX2, and PIX3. When a plurality of pixels PIX which emit visible light of different colors are combined in this way, the pixels PIX for each color are referred to as sub-pixels and a set of the plurality of pixels PIX is referred to as a pixel in some cases. In the present embodiment, the part corresponding to the sub-pixel mentioned above is referred to as the pixel PIX.

The wiring 31 is electrically connected to each of the drain electrode ED of the switching element SW and the anode electrode 20EA of the LED element 20. The wiring 32 is connected to a source electrode ES of the switching element SW. In the example shown in FIG. 3, the wiring 32 has a curved structure, one end of the wiring 32 is connected to the source electrode ES of the switching element SW, and the other end of the wiring 32 is connected to the video signal wiring VL. The scanning signal line GL is used as the gate electrode EG of the switching element SW. Note that the layout shown in FIG. 3 is an example, and there are various modifications. For example, as a modification related to FIG. 3, there may be a structure in which the switching element SW has a gate electrode (not shown) and the gate electrode is connected to the scanning signal line GL. In this modification, the scanning signal line GL may be arranged at a position which does not overlap with a semiconductor layer 50.

As shown in FIG. 4, the display device DSP1 is a substrate including the substrate 10 and a plurality of insulating layers stacked on the substrate 10. The plurality of insulating layers of the display device DSP1 include an inorganic insulating layer 11, an inorganic insulating layer 12, and an inorganic insulating layer 13 stacked on the substrate 10. The substrate 10 has a surface 10f and a surface 10b opposite to the surface 10f. Each of the inorganic insulating layers 11, 12, and 13 is stacked on the surface 10f of the substrate 10.

The switching element SW includes the inorganic insulating layer 12 formed on a substrate 10, the semiconductor layer 50 formed on the inorganic insulating layer 12, the drain electrode ED connected to a drain region of the semiconductor layer 50, the source electrode ES connected to a source region of the semiconductor layer 50, and the inorganic insulating layer 13 covering the semiconductor layer 50. Each of the wiring 31 and the wiring 32 includes a metal wiring portion 30A made of a first metal material such as copper or a copper alloy and a metal wiring portion 30B electrically connected to the wiring portion and made of a second metal material different from the first metal material. The second metal material is a metal material which is less likely to diffuse into the semiconductor layer 50 than the first metal material. In addition, in a region R1 which overlaps with the semiconductor layer 50 in a transparent plan view, the metal wiring portion 30B is arranged, and the metal wiring portion 30A is not arranged. In a region R2 which is arranged so as to surround the region R1 and does not overlap with the semiconductor layer 50, each of the metal wiring portion 30A and the metal wiring portion 30B which extends while overlapping with the metal wiring portion 30A is arranged. The metal wiring portion 30B arranged in the region R1 is covered with an organic insulating film 40.

The example shown in FIG. 4 is an example of a bottom gate type in which the gate electrode GE is located between the semiconductor layer 50 and the substrate 10. In the case of the bottom gate type, a part of the inorganic insulating layer 12 located between the gate electrode GE and the semiconductor layer 50 functions as a gate insulating layer. Also, the inorganic insulating layer 12 also functions as a base layer for forming the semiconductor layer 50. Note that the position of the gate electrode GE is not limited to the example shown in FIG. 4, and a top gate type described later as a modification may also be adopted.

The material constituting each of the inorganic insulating layers 11, 12, and 13 is not particularly limited. For example, silicon oxide (SiO₂) and silicon nitride (SiN) can be presented. Also, the semiconductor layer 50 is, for example, a semiconductor film formed by doping a silicon film made of silicon with impurities of P conductivity type or N conductivity type.

Each of the source electrode ES and the drain electrode ED is a contact plug for making electrical contact with either the source region or the drain region of the semiconductor layer 50. The material of the contact plug is, for example, tungsten. As a modification related to FIG. 4, there is a case in which contact holes exposing the source and drain regions of the semiconductor layer 50 are formed in the inorganic insulating layer 13 and the metal wiring portion 30B is buried in the contact holes. In this case, the metal wiring portion 30B is in contact with the semiconductor layer 50, and the contact interface between the metal wiring portion 30B and the semiconductor layer 50 can be regarded as the drain electrode ED and the source electrode ES.

The metal material constituting the metal wiring portion 30B may be any metal material as long as it is less likely to diffuse into the semiconductor layer 50 than the metal material constituting the metal wiring portion 30A. Examples of the metal material include aluminum and tantalum.

The inventors of this application have studied the use of a metal material made of copper or a copper alloy as the wiring material in order to reduce the resistance of the wiring. As a result, it has been found that, when the video signal wiring VL, the wiring 31, the wiring 32, and the wiring VSL shown in FIG. 3 are simply made of copper or a copper alloy, the wiring resistance can be reduced, but another problem arises. Namely, there arises a problem of the diffusion of copper used as a wiring material into the semiconductor layer 50 during the manufacturing process of the display device or due to the aging of the completed product. When copper diffuses into the semiconductor layer 50, the electrical characteristics of the semiconductor layer 50 are deteriorated, resulting in a failure in the electrical switching operation.

Therefore, the inventors of this application have studied a technique capable of reducing the resistance of wiring and suppressing the deterioration of the characteristics of the semiconductor layer 50 due to the diffusion of copper. As described with reference to FIG. 4, each of the wiring 31 and the wiring 32 of the display device DSP1 includes the metal wiring portion 30A made of the first metal material such as copper or a copper alloy and the metal wiring portion 30B electrically connected to the wiring portion and made of the second metal material different from the first metal material. Since the wirings 31 and 32 include the metal wiring portion 30A, the resistance of the wirings 31 and 32 can be reduced.

Also, in the region R1 overlapping with the semiconductor layer 50, the metal wiring portion 30B is arranged, and the metal wiring portion 30A is not arranged. Furthermore, the metal wiring portion 30B arranged in the region R1 is covered with the organic insulating film 40. The organic insulating film 40 is a film made of an organic material such as an acrylic resin. The organic insulating film 40 has a function of preventing the copper contained in the metal wiring portion 30A from leaking into the semiconductor layer 50 via the organic insulating film 40. As described above, in the case of the present embodiment, since the metal wiring portion 30A is not arranged in the region R1 and the region R1 is covered with the organic insulating film 40, the diffusion of copper into the semiconductor layer 50 can be suppressed.

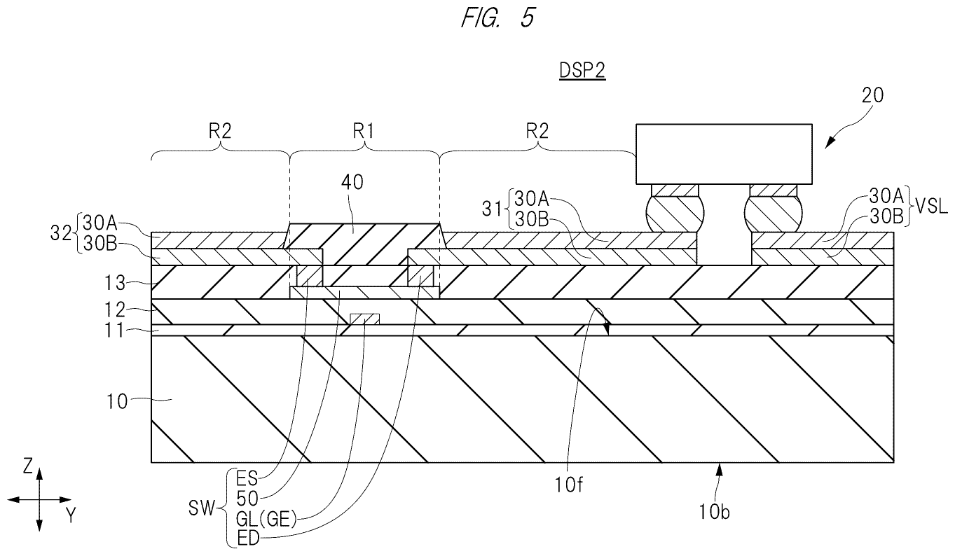

Incidentally, the diffusion of copper occurs, for example, during a heating process in the manufacturing process of a display device. From the viewpoint of preventing the diffusion of copper during the heating process, the diffusion of copper can be prevented as long as the metal wiring portion 30A is not arranged in the region R1 and the region R1 is covered with the organic insulating film 40. For example, even when the region R1 and the region R2 are adjacent to each other as in a display device DSP2 shown in FIG. 5 as a modification related to FIG. 4, the diffusion of copper can be prevented if the metal wiring portion 30A is not arranged in the region R1 and the region R1 is covered with the organic insulating film 40. FIG. 5 is an enlarged cross-sectional view showing a modification related to FIG. 4.

However, in addition to the diffusion of copper which occurs during the heating process in the manufacturing process of the display device, copper may also gradually diffuse through the inorganic insulating layer 13 and the inorganic insulating layer 12 shown in FIG. 4 due to the aging of the completed product. From the viewpoint of suppressing the deterioration of the semiconductor layer 50 due to diffusion caused by such aging, it is preferable that the region in which the metal wiring portion 30A is not arranged is present in a range wider than the region R1 shown in FIG. 1.

In the case of the display device DSP1 shown in FIG. 3 and FIG. 4, the region R1 and the region R2 are spaced apart from each other in a transparent plan view. A region R3 which does not overlap with the semiconductor layer 50 and is in contact with the region R2 is present between the region R1 and the region R2. In the region R3, the metal wiring portion 30B is arranged, and the metal wiring portion 30A is not arranged. The metal wiring portion 30B arranged in the region R3 is covered with the organic insulating film 40.

In the case of the display device DSP1, the region R3 in which the metal wiring portion 30A is not arranged is provided between the region R1 and the region R2, and the region R3 is covered with the organic insulating film 40. In this case, the distance between the metal wiring portion 30A containing copper and the semiconductor layer 50 can be made larger as compared with the display device DSP2 shown in FIG. 5. As a result, even when the diffusion of copper due to aging is taken into consideration, deterioration of the semiconductor layer 50 can be further suppressed.

In addition, as shown in FIG. 3, the organic insulating film 40 is partially formed in the region R1 and the region R3 in the present embodiment. In other words, the region R2 includes a part in which the organic insulating film 40 is not formed. As shown in FIG. 4, in the part of the region R2 in which the organic insulating film 40 is not formed, the metal wiring portion 30A and the metal wiring portion 30B are in contact with each other. The region R2 includes a region in which the metal wiring portion 30A and the metal wiring portion 30B extend in the same direction (Y direction in the example shown in FIG. 4) while being in contact with each other. This also applies to the display device DSP2 shown in FIG. 5.

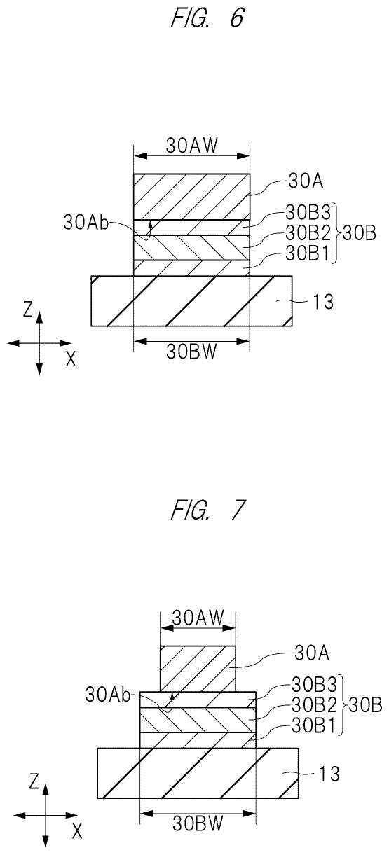

As shown in FIG. 6, the metal wiring portion 30B is a stacked film including a first film 30B1 made of titanium, a second film 30B2 covering the first film 30B1 and made of aluminum, and a third film 30B3 covering the second film 30B2 and made of titanium. FIG. 6 is an enlarged cross-sectional view showing a configuration example of the metal wiring portion shown in FIG. 4 and FIG. 5. The metal wiring portion 30B shown in FIG. 6 has a proven record in use as a wiring member for display devices, and it is known that there is no problem of diffusion of metal components into the semiconductor layer 50 or the like. By interposing a conductive member, into which metal components are less likely to diffuse, between the metal wiring portion 30A and the inorganic insulating layer 13 in this way, it is possible to suppress the diffusion of copper into the inorganic insulating layer 13. As a result, the amount of copper that reaches the semiconductor layer 50 shown in FIG. 4 or FIG. 5 can be reduced. In other words, the metal wiring portion 30B functions as a diffusion prevention film which prevents the diffusion of copper contained in the metal wiring portion 30A.

From the viewpoint of improving the function of the metal wiring portion 30B as a diffusion prevention film, it is preferable to reduce the contact area between the metal wiring portion 30A and the inorganic insulating layer 13. In addition, from the viewpoint of improving the function of the metal wiring portion 30B as a diffusion prevention film, it is particularly preferable that the metal wiring portion 30A and the inorganic insulating layer 13 are not in contact with each other and are spaced apart from each other. As shown in FIG. 6, in the case of the present embodiment, a wiring width 30AW of the metal wiring portion 30A is equal to or smaller than a wiring width 30BW of the metal wiring portion 30B in the region in which the metal wiring portion 30A and the metal wiring portion 30B are in contact with each other. Further, the entire lower surface 30Ab of the metal wiring portion 30A is in contact with the metal wiring portion 30B. Note that FIG. 6 shows an example in which the wiring width 30AW is equal to the wiring width 30BW, but there is also a case in which the wiring width 30AW is smaller than the wiring width 30BW as shown in FIG. 7 as a modification. FIG. 7 is an enlarged cross-sectional view showing a modification related to FIG. 6.

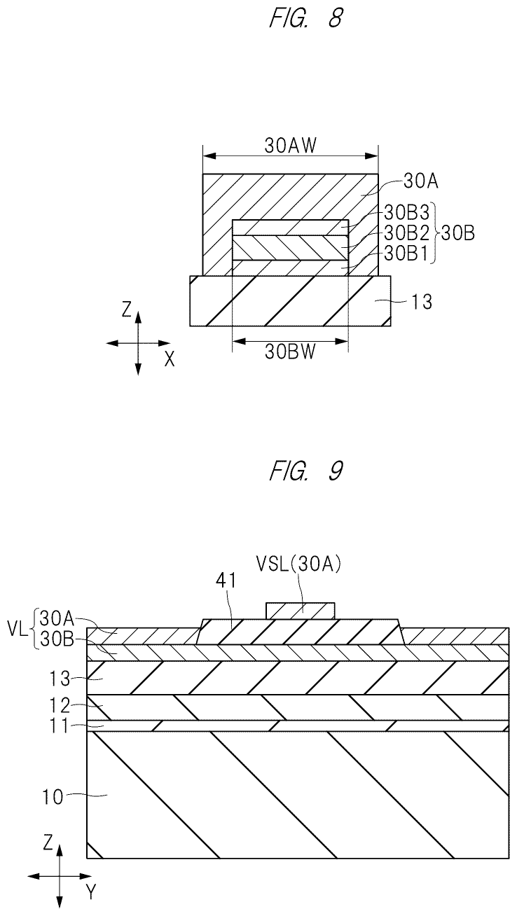

Meanwhile, there is a structure shown in FIG. 8 as another modification. FIG. 8 is an enlarged cross-sectional view showing another modification related to FIG. 6. When the second metal material constituting the metal wiring portion 30B contains aluminum as in the present embodiment, an exposed part of the second film 30B2 made of aluminum may be eroded, for example, during an etching process for patterning the metal wiring portion 30A containing copper or a copper alloy. From the viewpoint of preventing the erosion of the aluminum film described above, it is preferable that at least the second film 30B2 is covered with the metal wiring portion 30A as shown in FIG. 8. In the example shown in FIG. 8, the second metal material contains aluminum. In addition, in the region in which the metal wiring portion 30A and the metal wiring portion 30B are in contact with each other, the side and upper surfaces of the metal wiring portion 30B are covered with the metal wiring portion 30A.

Each of FIG. 6 to FIG. 8 is an enlarged cross-sectional view showing a part of the region in which the metal wiring portion 30A and the metal wiring portion 30B shown in FIG. 4 or 5 are in contact with each other. However, in the region in which the metal wiring portion 30A and the metal wiring portion 30B are in contact with each other in FIG. 4 and FIG. 5, the metal wiring portion 30A and the metal wiring portion 30B have any one of the structures shown in FIG. 6, FIG. 7, and FIG. 8. For example, when the structure of a part of the region in which the metal wiring portion 30A and the metal wiring portion 30B are in contact in FIG. 4 and FIG. 5 is the structure shown in FIG. 6, the structure of the region in which the metal wiring portion 30A and the metal wiring portion 30B are in contact is the structure shown in FIG. 6 over the entire range shown in FIG. 4 and FIG. 5.

### Structure of Wiring Intersecting Portion

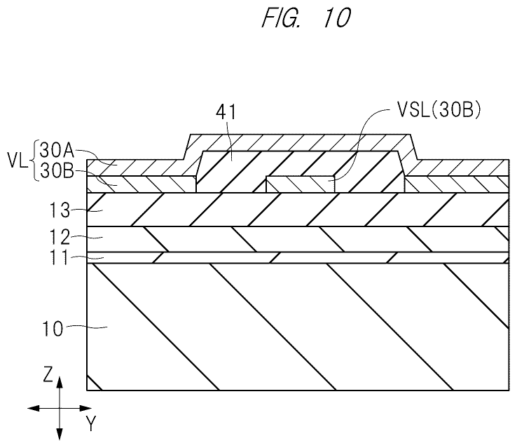

Next, a structure of a wiring intersecting portion LXP in which the video signal wiring VL and the wiring VSL intersect in the example shown in FIG. 3 will be described. FIG. 9 is an enlarged cross-sectional view taken along the line B-B in FIG. 3. As shown in FIG. 3, the display device DSP1 further includes the video signal wiring VL which extends over the plurality of pixels PIX (see FIG. 2) along the Y direction and is electrically connected to the wiring 32 and the wiring VSL which extends over the plurality of pixels PIX along the X direction intersecting with the Y direction (orthogonal to the Y direction in FIG. 3) and is electrically connected to the cathode electrode 20EK of the LED element 20.

Each of the video signal wiring VL and the wiring VSL includes the metal wiring portion 30A and the metal wiring portion 30B. In the wiring intersecting portion LXP in which the video signal wiring VL and the wiring VSL intersect in a transparent plan view, the metal wiring portion 30B of one wiring of the video signal wiring VL and the wiring VSL (the video signal wiring VL in the example shown in FIG. 9) is formed as shown in FIG. 9. In the wiring intersecting portion LXP, a jumper insulating film 41 which covers the metal wiring portion 30B of one wiring (the video signal wiring VL in the example shown in FIG. 9) is formed. In the wiring intersecting portion LXP, the metal wiring portion 30A of the other wiring of the video signal wiring VL and the wiring VSL formed on the jumper insulating film 41 (the wiring VSL in the example shown in FIG. 9) is formed. In the wiring intersecting portion LXP, the metal wiring portion 30A of one wiring (the video signal wiring VL in the example shown in FIG. 9) and the metal wiring portion 30B of the other wiring (the wiring VSL in the example shown in FIG. 9) are not formed. The jumper insulating film 41 is made of the same material as the organic insulating film 40.

When the jumper insulating film 41 shown in FIG. 9 and the organic insulating film 40 shown in FIG. 4 are made of the same material (for example, acrylic resin), the jumper insulating film 41 and the organic insulating film 40 are manufactured together in the same process in the manufacturing process of the display device DSP1. In this case, it is possible to prevent the increase in the number of manufacturing steps due to the provision of the organic insulating film 40, and it is thus possible to prevent the decrease in the manufacturing efficiency of the display device DSP1. For example, in the manufacturing method of the display device DSP1 shown in FIG. 4 and the display device DSP2 shown in FIG. 5, an organic film constituting the organic insulating film 40 and the jumper insulating film 41 is applied and patterned after forming the metal wiring portion 30B on the inorganic insulating layer 13. Thereafter, a copper film or a copper alloy film constituting the metal wiring portion 30A is formed and is then patterned by etching or the like, thereby forming the metal wiring portion 30A. Thereafter, the LED element 20 is mounted.

Incidentally, although an embodiment in which the wiring VSL is formed on the jumper insulating film 41 has been described with reference to FIG. 9, there is also a case in which the metal wiring portion 30A of the video signal wiring VL is formed on the jumper insulating film 41 and the metal wiring portion 30B of the wiring VSL is arranged under the jumper insulating film 41 as shown in FIG. 10 as a modification. FIG. 10 is an enlarged cross-sectional view showing a modification related to FIG. 9. Even in the example shown in FIG. 10, it is possible to prevent the decrease in the manufacturing efficiency of the display device DSP1 due to the formation of the organic insulating film 40 if the jumper insulating film 41 and the organic insulating film 40 shown in FIG. 4 are made of the same material (for example, acrylic resin).

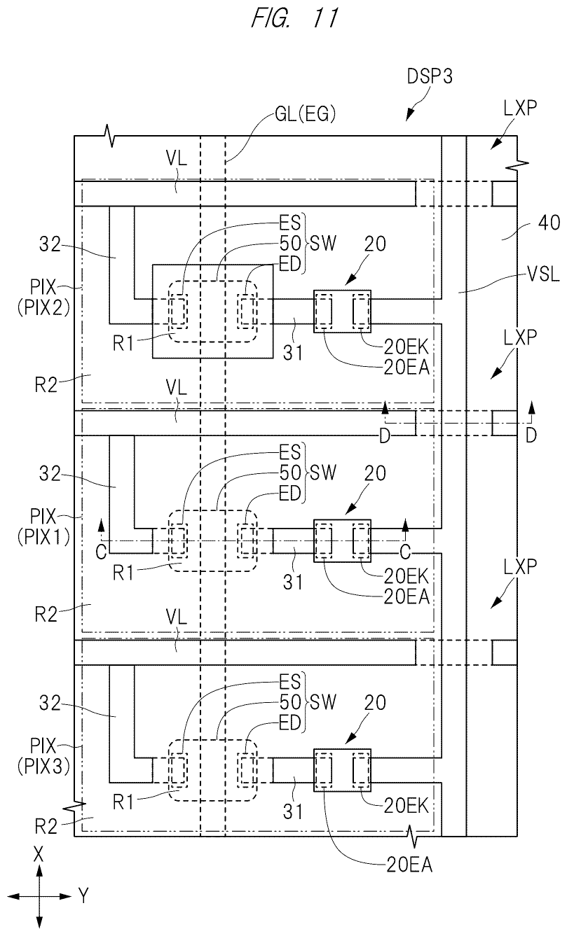

FIG. 3 shows an example in which the jumper insulating film 41 is partially formed in each of the plurality of wiring intersecting portions LXP. However, there are various modifications in the shape of the jumper insulating film 41. For example, a strip-shaped jumper insulating film 41 extending in the X direction can be formed by connecting a plurality of jumper insulating films 41 shown in FIG. 3 to each other. Alternatively, there is also a case in which the organic insulating film 40 and the jumper insulating film 41 are connected to form an integrated organic insulating film 40 as in a display device DSP3 shown in FIG. 11 to FIG. 13 described later.

### Modification of Organic Insulating Film

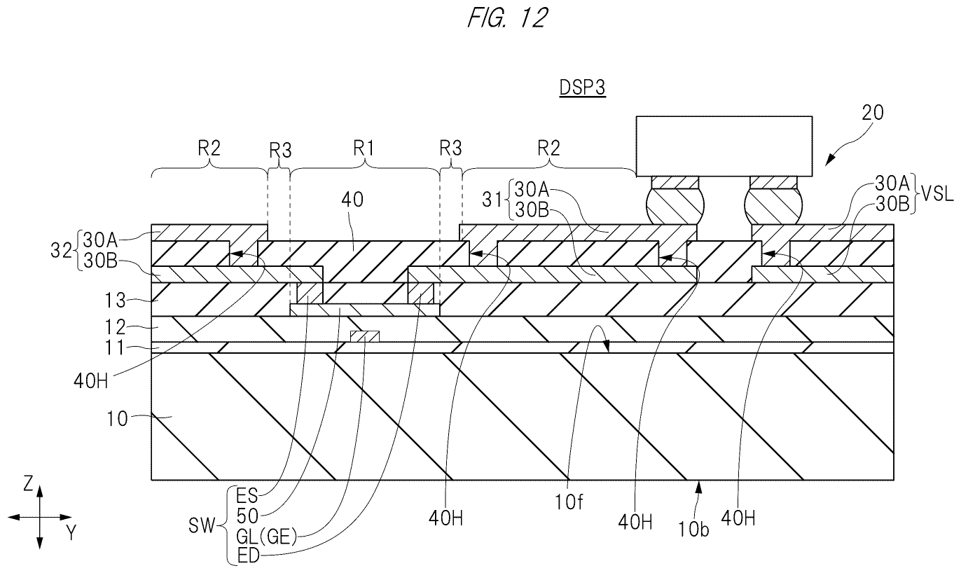

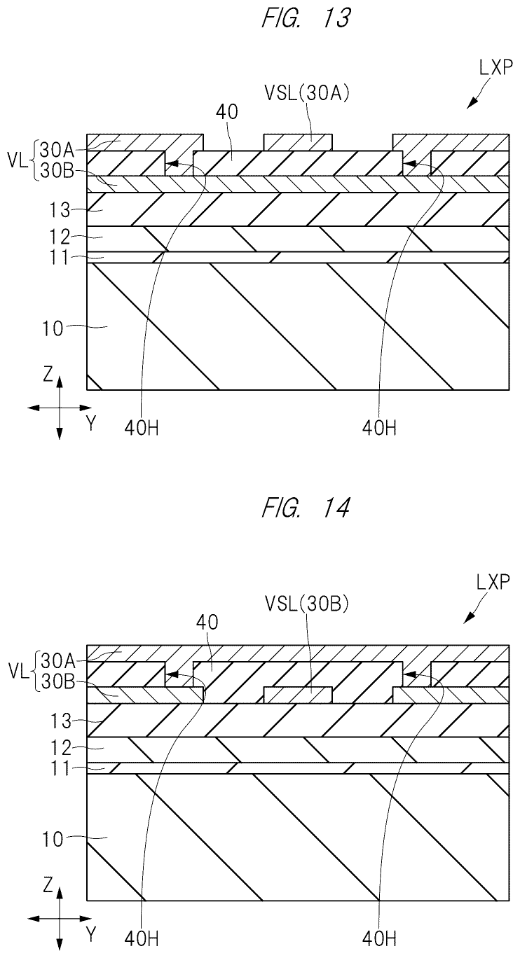

Next, a modification of the organic insulating film shown in FIG. 4 and FIG. 5 will be described. FIG. 11 is a transparent plan view showing a modification related to FIG. 3. FIG. 12 is an enlarged cross-sectional view taken along the line C-C in FIG. 11. FIG. 13 is an enlarged cross-sectional view taken along the line D-D in FIG. 11. FIG. 14 is an enlarged cross-sectional view showing a modification related to FIG. 13.

A display device DSP3 shown in FIG. 11 to FIG. 13 differs from the display device DSP1 shown in FIG. 3 and FIG. 4 in that the metal wiring portion 30B is entirely covered with the organic insulating film 40. In the case of the display device DSP1, the inorganic insulating layer 13 is entirely covered with the organic insulating film 40. Most of the metal wiring portion 30A is formed on the organic insulating film 40. Therefore, the possibility that the component contained in the metal wiring portion 30A diffuses into the inorganic insulating layer 13 can be reduced. Also, by increasing the area of the organic insulating film 40, the flatness of the upper surface of the organic insulating film 40 is improved. As a result, the flatness of the metal wiring portion 30A formed on the organic insulating film 40 is also improved. For example, by improving the flatness of the metal wiring portion 30A in the part on which the LED element 20 is mounted, the mounting process of the LED element 20 can be performed with high precision. Further, by improving the flatness of the organic insulating film 40 which is the base layer of the metal wiring portion 30A, the risk of damaging the metal wiring portion 30A can be reduced.

The structure of the display device DSP3 shown in FIG. 11 to FIG. 13 can be expressed as follows. That is, the region R2 includes a region in which the metal wiring portion 30A and the metal wiring portion 30B extend in the same direction while being spaced apart from each other with the organic insulating film 40 interposed therebetween. However, it is necessary to electrically connect the metal wiring portion 30A and the metal wiring portion 30B. In this modification, the metal wiring portion 30A and the metal wiring portion 30B are in contact and electrically connected with each other through contact holes 40H formed in the organic insulating film 40.

As shown in FIG. 13 and FIG. 14, in the case of this modification, the structure of the wiring intersecting portion LXP can be described as follows. In the wiring intersecting portion LXP in which the video signal wiring VL and the wiring VSL intersect in a transparent plan view, the metal wiring portion 30B of one wiring of the video signal wiring VL and the wiring VSL (the video signal wiring VL in the example shown in FIG. 13, the wiring VSL in the example shown in FIG. 14) is formed. In the wiring intersecting portion LXP, the organic insulating film 40 which covers the metal wiring portion 30B of one wiring is formed. In the wiring intersecting portion LXP, the metal wiring portion 30A of the other wiring of the video signal wiring VL and the wiring VSL formed on the organic insulating film 40 (the wiring VSL in the example shown in FIG. 13, the video signal wiring VL in the example shown in FIG. 14) is formed. In the wiring intersecting portion LXP, the metal wiring portion 30A of one wiring and the metal wiring portion 30B of the other wiring are not formed.

Although the display device DSP3 has been described as a modification of the display device DSP1 shown in FIG. 3, it may be applied in combination with the display device DSP1 shown in FIG. 5. Further, the structure of the metal wiring portion 30A and the metal wiring portion 30B can be any of the structural examples shown in FIG. 6 to FIG. 8.

### Other Modifications

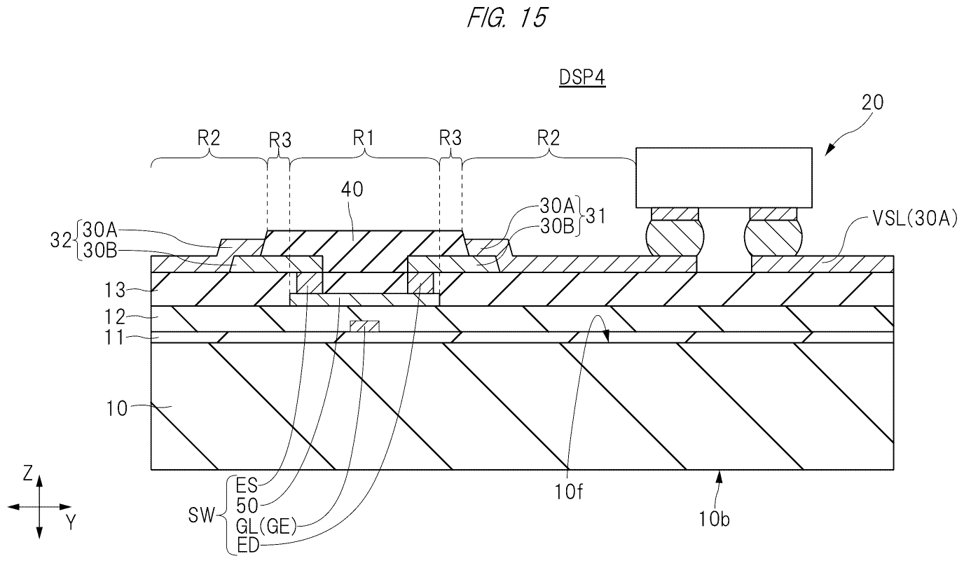

Next, modifications other than those described above will be described. FIG. 15 is an enlarged cross-sectional view showing another modification related to FIG. 4. A display device DSP4 shown in FIG. 15 differs from the display device DSP1 shown in FIG. 4 in the structure of the wiring 31 and the wiring 32. In the case of the display device DSP4, the region R2 has a part in which the metal wiring portion 30A is formed directly on the inorganic insulating layer 13 without the metal wiring portion 30B interposed therebetween. As described above, from the viewpoint of suppressing the diffusion of copper, it is preferable that the area of the contact portion between the inorganic insulating layer 13 and the metal wiring portion 30A is as small as possible. However, as shown in FIG. 15, if the metal wiring portion 30A is not arranged and the metal wiring portion 30B is covered with the organic insulating film 40 at least in the region R1 overlapping with the semiconductor layer 50, the diffusion of copper due to the heating process can be suppressed.

This also applies to the wiring intersecting portions LXP shown in FIG. 3 and FIG. 11. Although not shown, for example, in the examples shown in FIG. 9, FIG. 10, FIG. 13, and FIG. 14, there may be a case in which the metal wiring portion 30B is not formed and each of the video signal wiring VL and the wiring VSL is formed of only the metal wiring portion 30A. Even in this case, the diffusion of copper into the semiconductor layer 50 can be suppressed if the wiring intersecting portion LXP and the semiconductor layer 50 are spaced apart from each other.

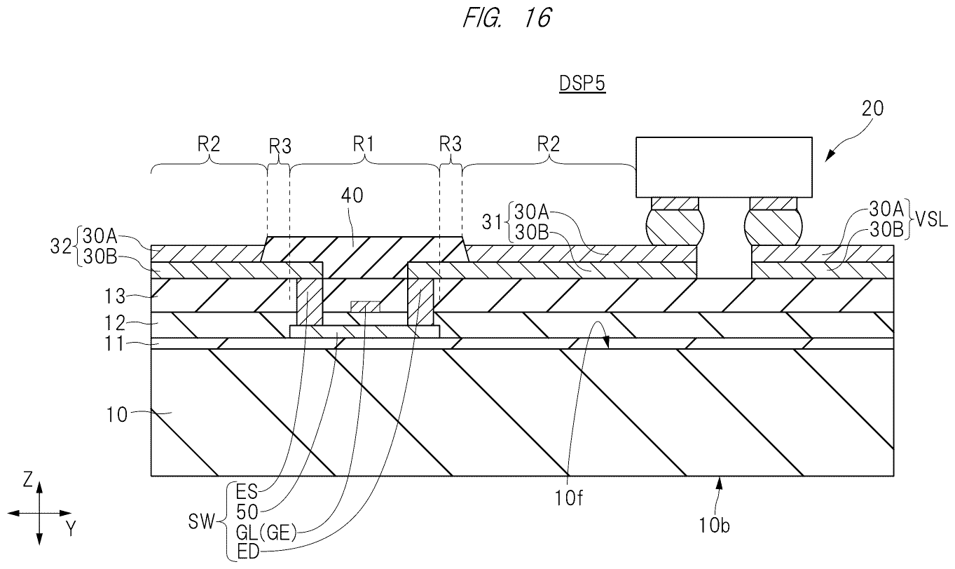

FIG. 16 is an enlarged cross-sectional view showing another modification related to FIG. 4. A display device DSP5 shown in FIG. 16 differs from the display device DSP1 shown in FIG. 4 in that the structure of the switching element SW is a so-called top gate type. In the case of the top gate type, the semiconductor layer 50 is formed on the inorganic insulating layer 11. In addition, the gate electrode GE is formed on the semiconductor layer 50 via the inorganic insulating layer 12. In this case, the part of the inorganic insulating layer 12 arranged between the gate electrode GE and the semiconductor layer 50 functions as a gate insulating film. In addition, each of the source electrode SE and the drain electrode DE extends in a thickness direction of the display device DSP5 (the Z direction shown in FIG. 16) so as to connect the metal wiring portion 30B formed on the inorganic insulating layer 13 and the semiconductor layer 50.

In the case of the top gate type, the distance between the metal wiring portion 30A and the semiconductor layer 50 becomes longer as compared with the bottom gate type shown in FIG. 4. This is preferable from the viewpoint of preventing the diffusion of copper from reaching the semiconductor layer 50. Although a representative modification related to FIG. 4 has been described in FIG. 16, it goes without saying that the top gate type may be applied to other modifications.

In the foregoing, the embodiment and typical modifications have been described, but the above-described technique can be applied to various modifications other than the modifications described above. For example, the above-described modifications can be used in combination.

A person having ordinary skill in the art can conceive of various alterations and corrections within a range of the idea of the present invention, and it is interpreted that the alterations and corrections also belong to the scope of the present invention. For example, the embodiment obtained by performing addition or elimination of components or design change or the embodiment obtained by performing addition or reduction of process or condition change to the embodiment described above by a person having an ordinary skill in the art is also included in the scope of the present invention as long as it includes the gist of the present invention.

The present invention can be applied to display devices and electronic devices incorporating display devices.

What is claimed is:

1. A display device comprising:
a plurality of pixels including a first pixel and arranged in a matrix;
a first switching element formed in the first pixel;
a first light emitting element mounted in the first pixel;
a first wiring electrically connected to each of a drain electrode of the first switching element and an anode electrode of the first light emitting element; and
a second wiring connected to a source electrode of the first switching element,
wherein the first switching element includes:
a first inorganic insulating layer formed on a first substrate;
a semiconductor layer formed on the first inorganic insulating layer;
the drain electrode connected to a drain region of the semiconductor layer;
the source electrode connected to a source region of the semiconductor layer; and
a second inorganic insulating layer configured to cover the semiconductor layer,
wherein each of the first wiring and the second wiring includes:
a first metal wiring portion made of a first metal material such as copper or a copper alloy; and
a second metal wiring portion electrically connected to the first metal wiring portion and made of a second metal material different from the first metal material, and
wherein, in a transparent plan view, the second metal wiring portion is arranged and the first metal wiring portion is not arranged in a first region which overlaps with the semiconductor layer, each of the first metal wiring portion and the second metal wiring portion extending while overlapping with the first metal wiring portion is arranged in a second region which is arranged so as to surround the first region and does not overlap with the semiconductor layer, and the second metal wiring portion arranged in the first region is covered with an organic insulating film.

2. The display device according to claim 1,
wherein, in a transparent plan view, the first region and the second region are spaced apart from each other, a third region which does not overlap with the semiconductor layer and is in contact with the first region is present between the first region and the second region, the second metal wiring portion is arranged and the first metal wiring portion is not arranged in the third region, the second metal wiring portion arranged in the third region is covered with the organic insulating film, and the second metal material is less likely to diffuse into the semiconductor layer than the first metal material.

3. The display device according to claim 1,
wherein the second region includes a region in which the first metal wiring portion and the second metal wiring portion extend in the same direction while being in contact with each other.

4. The display device according to claim 3,
wherein, in the region in which the first metal wiring portion and the second metal wiring portion are in contact with each other, a wiring width of the first metal wiring portion is smaller than a wiring width of the second metal wiring portion, and an entire lower surface of the first metal wiring portion is in contact with the second metal wiring portion.

5. The display device according to claim 3,
wherein the second metal material contains aluminum, and
wherein, in the region in which the first metal wiring portion and the second metal wiring portion are in contact with each other, side and upper surfaces of the second metal wiring portion are covered with the first metal wiring portion.

6. The display device according to claim 1,
wherein the second region includes a region in which the first metal wiring portion and the second metal wiring portion extend in the same direction while being spaced apart from with each other with the organic insulating film interposed therebetween.

7. The display device according to claim 6,
wherein the first metal wiring portion and the second metal wiring portion are in contact and electrically connected with each other through contact holes formed in the organic insulating film.

8. The display device according to claim 1, further comprising:
a video signal wiring extending over a plurality of pixels along a first direction and electrically connected to the second wiring; and
a third wiring extending over a plurality of pixels along a second direction intersecting with the first direction and electrically connected to a cathode electrode of the first light emitting element,
wherein each of the video signal wiring and the third wiring includes the first metal wiring portion and the second metal wiring portion,
wherein, in a wiring intersecting portion in which the video signal wiring and the third wiring intersect in a transparent plan view, the second metal wiring portion of one wiring of the video signal wiring and the third wiring, a jumper insulating film which covers the second metal wiring portion of the one wiring, and the first metal wiring portion of the other wiring of the video signal wiring and the third wiring formed on the jumper insulating film are formed,
wherein the first metal wiring portion of the one wiring and the second metal wiring portion of the other wiring are not formed in the wiring intersecting portion, and
wherein the jumper insulating film is made of the same material as the organic insulating film.

9. The display device according to claim 1,
wherein the second metal wiring portion is a stacked film of a first film made of titanium, a second film which covers the first film and is made of aluminum, and a third film which covers the second film and is made of titanium.

10. The display device according to claim 2,
wherein the second region includes a region in which the first metal wiring portion and the second metal wiring portion extend in the same direction while being in contact with each other.

11. The display device according to claim 10,
wherein, in the region in which the first metal wiring portion and the second metal wiring portion are in contact with each other, a wiring width of the first metal wiring portion is smaller than a wiring width of the second metal wiring portion, and an entire lower surface of the first metal wiring portion is in contact with the second metal wiring portion.

12. The display device according to claim 10,
wherein the second metal material contains aluminum, and
wherein, in the region in which the first metal wiring portion and the second metal wiring portion are in contact with each other, side and upper surfaces of the second metal wiring portion are covered with the first metal wiring portion.

13. The display device according to claim 2,
wherein the second region includes a region in which the first metal wiring portion and the second metal wiring portion extend in the same direction while being spaced apart from with each other with the organic insulating film interposed therebetween.

14. The display device according to claim 13,
wherein the first metal wiring portion and the second metal wiring portion are in contact and electrically connected with each other through contact holes formed in the organic insulating film.

15. The display device according to claim 2,
wherein the second metal wiring portion is a stacked film of a first film made of titanium, a second film which covers the first film and is made of aluminum, and a third film which covers the second film and is made of titanium.
